(19) United States
(12) Patent Application Publication
(10) Pub. No.: US 2025/0323405 A1
(43) Pub. Date: Oct. 16, 2025

(54) DUAL-BAND AND DUAL-POLARIZED INTERFEROMETRIC RECEIVER AND METHODS THEREOF

(71) Applicants: Huawei Technologies Canada Co., Ltd., Kanata (CA); la corporation de I' École Polytechnique de Montréal, Montreal (CA)

(72) Inventors: Jie Deng, Montreal (CA); Pascal Burasa, Montreal (CA); Ke Wu, Saint-Laurent (CA)

(21) Appl. No.: 19/253,070

(22) Filed: Jun. 27, 2025

Related U.S. Application Data
(63) Continuation of application No. PCT/CA2023/050044, filed on Jan. 17, 2023.

(51) Int. Cl. H01P 5/16; H03K 17/687; H04L 27/38

(52) U.S. Cl. CPC H01P 5/16; H03K 17/6871; H04L 27/38

(57) ABSTRACT

The present disclosure provides modules, arrays and methods for interferometric receivers for dual-band and dual-polarization signal modulation where the module comprises a plurality of oscillators for generating a plurality of carrier signals of a plurality of frequency bands, and a multiport circuit connected to the plurality of oscillators. The multiport circuit having a plurality of inputs each for receiving one of the plurality of carrier signals, a plurality of outputs, a plurality of quadrature hybrid couplers, power dividers, and power detectors.

### CROSS-REFERENCE TO RELATED APPLICATION

The present application is a continuation of Patent Cooperation Treaty Application Serial No. PCT/CA2023/050044, entitled “DUAL-BAND AND DUAL-POLARIZED INTERFEROMETRIC RECEIVER AND METHODS THEREOF,” filed on Jan. 17, 2023, the entirety of which is incorporated by reference herein.

### TECHNICAL FIELD

The present disclosure relates generally to wireless receivers, and in particular, to interferometric dual-band and dual-polarized receivers.

### BACKGROUND

Wireless communications systems are rapidly developing as they face accelerated demand for high-speed communications systems and the equipment used therein due an increasing number of a variety of applications such as smart devices, artificial intelligence, the internet of things, three-dimensional environmental mapping, three-dimensional media, autonomous cars, virtual and augmented reality, and or the like. As wireless technologies head towards increasing integration with autonomous and/or smart devices that quickly connect more things and people with services and functions, high quality transmission links meeting requirements such as low latency, high reliability, and fast synchronization are required to meet the demands of these applications.

Conventional interferometric receiver is for single-band and single-polarization transmission, require more energy consumption for data conversion, may be susceptible to noise and interference, and generally provide lower signal efficiency than multi-polarization signals.

### SUMMARY

The present disclosure provides methods, modules, and receiver arrays for multiport interferometric receiving and demodulating for dual-band and dual-polarization signals which may comprise quadrature hybrid couplers, power dividers, 90-degree phase shifters, and local oscillators, which may be implemented in a variety of technologies such as complementary-metal-oxide-semiconductor (CMOS).

According to one aspect of this disclosure, there is provided a module comprising: a first and a second receiving unit, each receiving unit comprising: a 90-degree phase shifter; a first and a second power divider, each power divider comprising a first input port, a second input port, and a output port; and a first and a second quadrature hybrid coupler, each quadrature hybrid coupler comprising a first port, a second port, a third port, and a fourth port, wherein: the first port of the first coupler is for being energized by a first oscillation signal, the second port of the first coupler is connected to the second input port of the first power divider, the third port of the first coupler is connected to the second input port of the second power divider, the fourth port of the first coupler is for being energized by a second oscillation signal, the first port of the second coupler is for being energized by a first input signal, the second port of the second coupler is connected to the first input port of the first power divider via the 90-degree phase shifter, the third port of the second coupler is connected to the first input port of the second power divider, and the fourth port of the second coupler is for being energized by a second input signal, wherein each of the output ports is for being energized by a demodulated output signal.

In an embodiment, the module further comprises a dual polarization antenna for receiving dual-band signals comprising vertically polarized components and horizontally polarized components, the antenna for providing: a first band signal comprising vertically polarized components as a first input signal to the first receiving unit; a second band signal comprising vertically polarized components as a second input signal to the first receiving unit; a third band signal comprising horizontally polarized components as a first input signal to the second receiving unit; and a fourth band signal comprising horizontally polarized components as a second input signal to the first receiving unit.

In an embodiment, each of the first and fourth ports of each second coupler of the first and the second receiving units comprises a band-pass frequency filter for converting: a first input signal to a first band-pass signal; and a second input signal to a second band-pass signal.

In an embodiment, each of the first and fourth ports of each second coupler comprises a low-noise amplifier for converting: a first band-pass signal to a first low-noise amplified signal; and a second band-pass signal to a second low-noise amplified signal.

In an embodiment, each output port of each power divider comprises a power detector to convert a demodulated output signal to a down-converted output signal.

In an embodiment, each output port of each power divider comprises a low-pass filter to convert a down-converted output signal to a low-pass output signal.

In an embodiment, each output port of each power divider comprises an operating amplifier to amplify a low-pass output signal to an amplified output signal.

In an embodiment, each output port of each power divider comprises an analog-to-digital converter to convert the amplified output signal to a digital output signal.

In an embodiment, the module further comprises a digital signal processor for processing each of the digital output signals.

In an embodiment, the module further comprises: a first local oscillator for producing the first oscillation signal; and a second local oscillator for producing the second oscillation signal.

In an embodiment, the first local oscillator and the second local oscillator have substantially the same characteristic impedance.

In an embodiment, the module comprises complementary metal-oxide-semiconductor (CMOS) components.

In an embodiment, the first and the second receiving units are vertically integrated on different CMOS layers.

In an embodiment, a receiving array comprises a plurality of the above modules.

According to one aspect of this disclosure, there is provided a method comprising: providing a first oscillating signal and a second oscillating signal to a first receiving unit to ports of a first quadrature hybrid coupler interconnected to a second quadrature hybrid coupler, the couplers interconnected with power dividers; providing the first oscillating signal and the second oscillating signal to a second receiving unit to ports of a third quadrature hybrid coupler interconnected to a fourth quadrature hybrid coupler, the couplers interconnected with power dividers; receiving a dual-band, dual-polarized signal; demodulating a first band signal of the dual-band, dual-polarized signal comprising vertically polarized components using the first receiving unit to provide a first demodulated output signal; demodulating a second band signal of the dual-band, dual-polarized signal comprising vertically polarized components using the first receiving unit to provide a second demodulated output signal; demodulating a third band signal of the dual-band, dual-polarized signal comprising horizontally polarized components using the second receiving unit to provide a third demodulated output signal; and demodulating a fourth band signal of the dual-band, dual-polarized signal comprising horizontally polarized components using the second receiving unit to provide a fourth demodulated output signal.

In an embodiment, the method further comprises applying a band-pass filter and a low-noise amplifier to: a first band intermediate signal the dual-band, dual-polarized signal comprising vertically polarized components to provide the first band signal; a second band intermediate signal of the dual-band, dual-polarized signal comprising vertically polarized components to provide the second band signal; a third band intermediate signal of the dual-band, dual-polarized signal comprising horizontally polarized components to provide the third band signal; and a fourth band intermediate signal of the dual-band, dual-polarized signal comprising horizontally polarized components to provide the fourth band signal.

In an embodiment, the method further comprises down-converting the first, the second, the third, and the fourth demodulated signals to a first, a second, a third, and a fourth down-converted output signal.

In an embodiment, the method further comprises applying a low-pass filter to the first, the second, the third, and the fourth down-converted output-signal to produce a first, a second, a third, and a fourth low-pass output signal.

In an embodiment, the method comprises amplifying the first, the second, the third, and the fourth low-pass output signal to a first, a second, a third, and a fourth amplified output signal.

In an embodiment, the method further comprises converting the first, the second, the third, and the fourth amplified signals to a first, a second, a third, and a fourth digital output signal.

In an embodiment, the method further comprises performing digital signal processing on the first, the second, the third, and the fourth digital output signals.

According to one aspect of this disclosure, there is provided an apparatus comprising means to carry out the above mentioned methods.

In an embodiment, the apparatus may comprise a receiver array mentioned above, a module mentioned above, or a chipset.

According to one aspect of this disclosure, there is provided a system comprising apparatus mentioned above and a transmitter.

### BRIEF DESCRIPTION OF THE DRAWINGS

For a more complete understanding of the disclosure, reference is made to the following description and accompanying drawings, in which:

FIG. 1A is a schematic of an embodiment of a receiver module using a parallel integration architecture;

FIG. 1B is a schematic of an embodiment of a receiver module using a vertical integration architecture;

FIG. 2 is a schematic of the receiver module of FIG. 1A using a single-layer substrate-integrated waveguide structure;

FIG. 3 is a schematic of the receiver module of FIG. 1B implemented in complementary metal-oxide-semiconductor (CMOS);

FIG. 4A is a schematic of a receiving unit in accordance with representative embodiments of the present disclosure;

FIG. 4B is a schematic of an alternative embodiment of a receiving unit using transistors in place of diodes and power dividers;

FIGS. 5A and 5B illustrate input and recovered vertically-polarized signals for a 16 quadrature amplitude modulation (QAM) signal with 50 mega samples per second (MSps) at a 24 gigahertz (GHz) carrier frequency;

FIG. 6 is a demodulated vertical polarization normalized constellation diagram of the recovered baseband signals of FIGS. 5A and 5B;

FIGS. 7A and 7B illustrate input and recovered horizontally-polarized signals for a 16 QAM signal with 50 MSps at a 24 GHz carrier frequency;

FIG. 8 is a demodulated horizontal polarization normalized constellation diagram of the recovered baseband signals of FIGS. 7A and 7B;

FIGS. 9A and 9B illustrate input and recovered vertically-polarized signals for a 16 QAM signal with 50 MSps at a 28 GHz carrier frequency;

FIG. 10 is a demodulated vertical polarization normalized constellation diagram of the recovered baseband signals of FIGS. 9A and 9B;

FIGS. 11A and 11B illustrate input and recovered horizontally-polarized signals for a 16 QAM signal with 50 MSps at a 28 GHz carrier frequency;

FIG. 12 is a demodulated horizontal polarization normalized constellation diagram of the recovered baseband signals of FIGS. 11A and 11B;

FIG. 13 is a schematic of a receiving array comprising modules of the present disclosure; and

FIG. 14 is a block diagram of a method for receiving and demodulating a dual-band and dual-polarized signal in accordance with representative embodiments of the present disclosure.

### DETAILED DESCRIPTION

Unless otherwise defined, all technical and scientific terms used herein generally have the same meaning as commonly understood by one of ordinary skill in the art to which this disclosure pertains. Exemplary terms are defined below for ease in understanding the subject matter of the present disclosure.

As a result of increased performance demands, stricter requirements and increasing technical specifications require better performing equipment in communications systems. Receivers are key components in such communications systems and in order to provide higher data throughput, wider bandwidth, improved selectivity, and lower power consumption, versatile receivers that maintain a small form factor, low cost, and long battery life, as well as meeting stringent electrical specifications are important.

Multiport interferometric technologies may be suitable for application in radio frequency (RF) front-end solutions for receiving and transmitting RF signals with lower cost and power consumption as a result of simple working principles as compared to alternative technologies. Conventional interferometric receivers generally comprise a six-port junction, four power detectors, and four data converters. Information is extracted from the received signal using linear interference between the modulated RF signal and the local oscillator (LO) signal. Data converters generally account for a significant portion of the power consumption of the convention interferometric receivers.

In some embodiments of the present disclosure, the number of required data converters is reduced as well as the overall system complexity. To address issues relating to channel fading and to improve the system's data rate, dual-band and dual-polarization modulation of signals is used. Dual-band operation, which includes transmission, propagation, and reception, facilitates simultaneously transmitting data on different frequency channels. The use of polarization selectivity in signal modulation may enable channel diversity. A dual-polarization receiver may support simultaneous independent data streams on the same carrier frequency, which may double the effective channel capacity at that carrier frequency. While multi-band and multi-polarization transmitters may offer high quality transmission, conventional multiport interferometric receivers generally cannot provide dual-band and dual-polarization transmission simultaneously. Some of embodiments disclosed herein provide interferometric receivers capable of simultaneously receiving dual-band and dual-polarized modulated signals for diverse wireless applications and services, suitable for multi-channel, multi-function, and multi-standard wireless systems.

Embodiments of receiver modules and receiver arrays may be used for multi-function applications such as sensing, imaging, angle/polarization detection, and/or the like. They may be used for portable devices, base stations, terminal devices, radar systems, satellites systems, and/or the like, and may be implemented with PCB, metallic waveguides, complementary metal-oxide-semiconductor (CMOS), silicon micromachining, and/or the like.

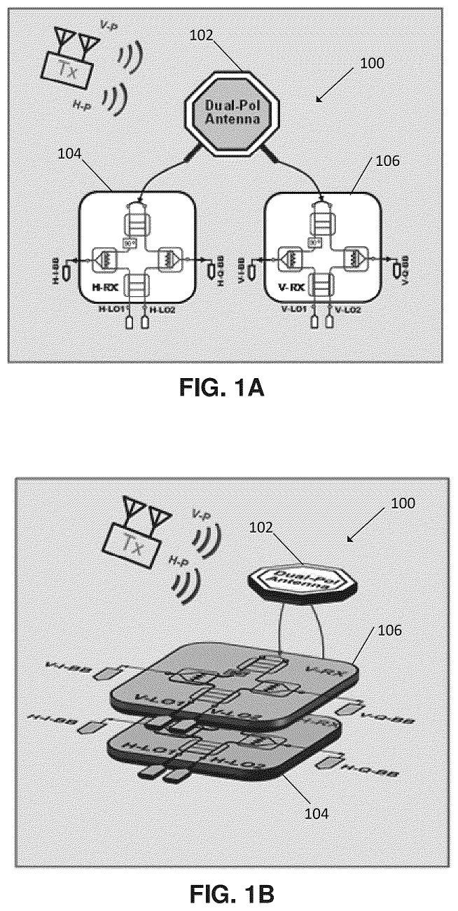

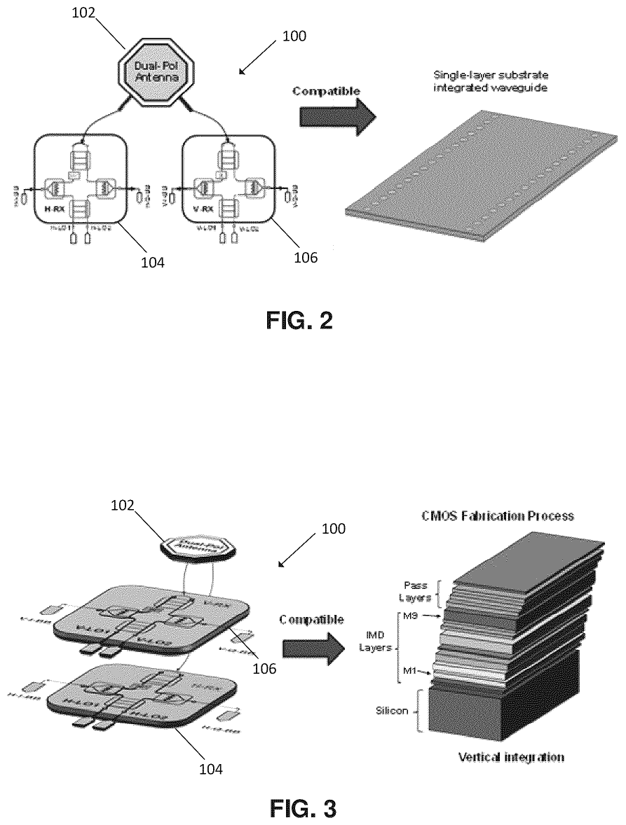

FIGS. 1A and 1B illustrate some embodiments of a receiver module 100 comprising a dual-polarization antenna 102, a first receiving unit 104, and a second receiving unit 106. The first receiving unit 104 and the second receiving unit 106 are each for demodulating an input signal. In some embodiments, the input signal of the first receiving unit 104 is a dual-band horizontally polarized signal and the input signal of the second receiving unit 106 is a dual-band vertically polarized signal. FIG. 1A illustrates a parallel integration architecture of the receiver module 100, wherein the first receiving unit 104 and the second receiving unit 106 are physically located side-by-side. FIG. 1B illustrates a vertical integration architecture of the receiver module 100, wherein the first receiving unit 104 is located physically below the second receiving unit 106. Each of these architectures has unique characteristics making them each suitable for different applications. For the parallel integration case, the first receiving unit 104 and the second receiving unit 106 of the receiver module 100 may be on the same physical layer, which may generally reduce the complexity of integration and fabrication costs as illustrated in FIG. 2. Such a single-layer solution on substrate-integrated waveguide technology as illustrated in FIG. 2 may be suitable for applications such as for thin portable devices. For the vertical integration case, the first receiving unit 104 and the second receiving unit 106 of the receiver module 100 may be on different physical layers of a multi-layer structure, which improves space efficiency by reducing the area or footprint required. Such a multi-layer structure may be suitable for applications such as CMOS as illustrated in FIG. 3. While both the parallel-integrated and vertically-integrated receiver module 100 may be compatible with CMOS, the vertically-integrated receiver module 100 would generally have the same footprint in CMOS as a single-polarization receiver.

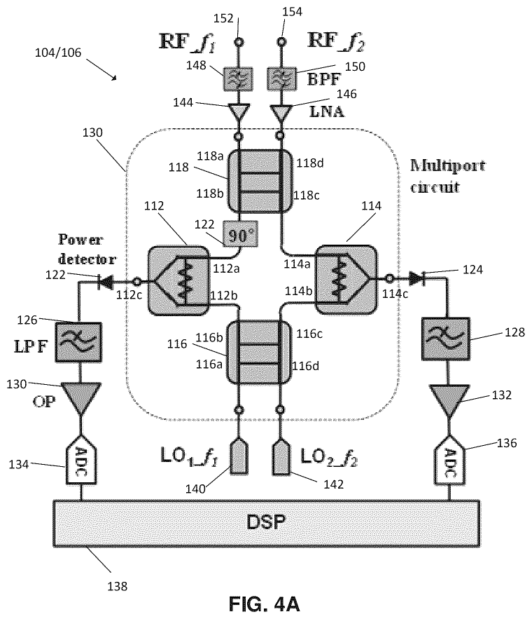

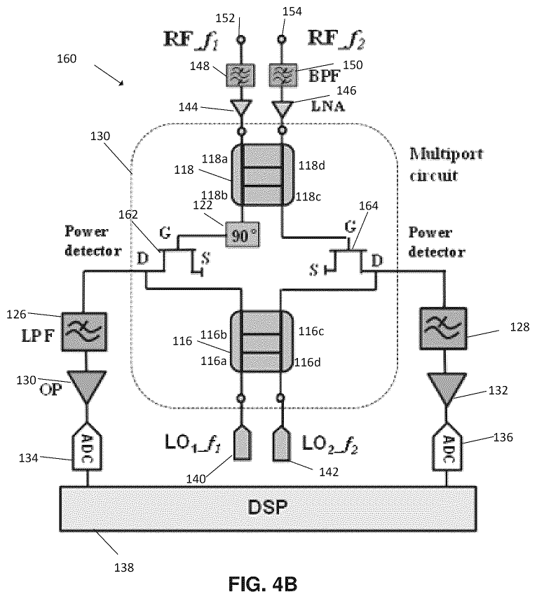

FIG. 4A shows an embodiment of the first receiving unit 104 and the second receiving unit 106, which are substantially identical. The receiving units 104 and 106 comprises multiport circuit 130, which comprises a first and a second power divider 112 and 114, a first and a second quadrature hybrid coupler 116 and 118, and a 90-degree phase shifter 122. The first power divider 112 comprising a first input port 112a, a second input port 112b, and an output port 112c, and the second power divider 114 comprising a first input port 114a, a second input port 114b, and an output port 114c. The first coupler 116 comprising a first port 116a, a second port 116b, a third port 116c, and a fourth port 116d. The second coupler 118 comprising a first port 118a, a second port 118b, a third port 118c, and a fourth port 118d. The first port 116a of the first coupler 116 is for being energized by a first oscillation signal, the second port 116b of the first coupler 116 is connected to the second input port 112b of the first power divider 112, the third port 116c of the first coupler 116 is connected to the second input port 114b of the second power divider 114, the fourth port 116d of the first coupler 116 is for being energized by a second oscillation signal, the first port 118a of the second coupler 118 is for being energized by a first input signal, the second port 118b of the second coupler 118 is connected to the first input port 112a of the first power divider 112 via the 90-degree phase shifter 122, the third port 118c of the second coupler 118 is connected to the first input port 114a of the second power divider 114, and the fourth port 114c of the second coupler 114 is for being energized by a second input signal.

As illustrated in FIGS. 1A to 3, the receiving units 104 and 106 may use the same dual polarization antenna 102 within a receiver module 100, the antenna 102 for receiving modulated a vertical polarization signal and a modulated horizontal polarization signal. The first receiver 104 and the second receiver 106 are substantially the same and directly connected to the antenna 102. The first receiving unit 104 may be for demodulating a vertical polarization RF signal and the second receiving unit 106 may be for demodulating a horizontal polarization RF signal. Referring to FIG. 4A, each receiving unit comprises two RF signal input ports 152 and 154, two LO signal input ports 116a and 116d, and two IQ signal output ports 112c and 114c. In some embodiments, the receiving units 104 and 106 comprise a first local oscillator 140 for providing the first oscillation signal to the first LO signal input port 116a and a second local oscillator 142 for providing the second oscillation signal to the second LO signal input port 116d. The first LO 140 and the second LO 142 may have substantially the same impedance. The input RF signals and LO signals may have different frequencies. For example, RF_f₁ and RF_f₂, LO_f₁, and LO_f₂. Therefore, the receiving units 104 and 106 may simultaneously support receiving and demodulating dual frequency independent data streams in a single interference circuit. The receiving units 104 and 106 may comprise a first and a second bandpass filter (BPF) 148 and 150 and a first and a second low-noise amplifier (LNA) 144 and 146 at each of the two RF signal input ports 152 and 154. During the operation of receiving unit 104 and 106, each modulated RF signal may first pass the BPF 148 and 150, which may be used as a pre-selection (band selection) filter for suppressing out-of-band interference and blockers, and provide band-pass signals. Then, the band-pass signals pass through the first and the second LNA 144 and 146 to provide low-noise amplified signals, which are provided to the multiport circuit 130. Two LO signals that match the operating frequency of two modulated RF signals may enter the multiport circuit 130. The modulated RF signals a_{_RF1} and a_{_RF2} may be expressed as | a_{_RF1}|[I(t)+jQ(t)]e^{jwRF1(t)} and |a_{_RF2}|[I(t)+jQ(t)]e^{jw RF2(t)}, respectively. The LO signals a_{_LO1} and a_{_LO2} may be expressed as |a_{LO1}|e^{j(wLO1(t)+θLO1)} and |a_{_LO2}|e^{j(wLO2(t)+θLO2)}, respectively. The output RF signal and LO signal of the multiport circuit is:

$${S}_{\_ RF} ( t ) = {{A}_{{\_ RF}_{1}} [ {I}_{1} {( t )}^{2} + {{Q}_{1} ( t )}^{2} ]}^{( 1 / 2 )} cos ( {ω}_{{\_ RF}_{1}} t + {θ}_{{\_ RF}_{1}} ) + {{A}_{{\_ RF}_{2}} [ {I}_{2} {( t )}^{2} + {{Q}_{2} ( t )}^{2} ]}^{( 1 / 2 )} cos ( {ω}_{{\_ RF}_{2}} t + {θ}_{{\_ RF}_{2}} ) \qquad ( 1 )$$

$${S}_{\_ LO} ( t ) = {A}_{{\_ LO}_{1}} * cos ( {ω}_{{\_ LO}_{1}} t + {Φ}_{{\_ LO}_{1}} ) + {A}_{{\_ LO}_{2}} * cos ( {ω}_{{\_ LO}_{2}} t + {Φ}_{{\_ LO}_{2}} ) \qquad ( 2 )$$

Where A_{_RF1}, A_{_RF2}, A_{_LO1}, and A_{_LO2} is the signal amplitude after the multiport circuit 130. θ_{_RF1}, θ_{_RF2}, Φ_{_LO1}, and Φ_{_LO2} is the signal phase after the multiport circuit 130. To provide concurrent dual-band operation, the RF signal and LO signal should meet the following conditions:

$${ω}_{{\_ IF}_{1}} = \vert {ω}_{{\_ LO}_{1}} - {ω}_{{\_ RF}_{1}} \vert > 3 B {W}_{{\_ RF}_{1}} / 2 \qquad ( 3 )$$

$$\vert {ω}_{{\_ IF}_{2}} - {ω}_{{\_ IF}_{1}} \vert > ( B {W}_{{\_ RF}_{1}} + B {W}_{{\_ RF}_{1}} ) / 2 \qquad ( 4 )$$

Then, the modulated RF signals and two LO signals are superposed through linear interference by the multiport circuit 130 under different relative phase conditions. The superposed RF and LO signals enter power detectors for down-conversion to provide down-converted output signals. The power detector may be a diode 122 and 124 as shown in FIG. 4A. In an alternative embodiment, the receiving units 104 and 106 may use a transistor 162 and 164 in place of the diode 122 and 124 and the power dividers 112 and 114 as shown in FIG. 4B. The power detectors operate in their square-law region. Thus, the output signal after the power detector includes rectified wave component, difference frequency component, sum frequency component, and high-order harmonic components, where the rectified wave component and difference frequency component are as follows:

$${S}_{\_ out} ( t ) = {r}^{2} / 2 [ {A}_{{\_ RF}_{1}}^{2} {G}_{{\_ RF}_{1}}^{2} [ {{I}_{1} ( t )}^{2} + {{Q}_{1} ( t )}^{2} ] + {A}_{{\_ RF}_{2}}^{2} {G}_{{\_ RF}_{2}}^{2} [ {{I}_{2} ( t )}^{2} + {{Q}_{2} ( t )}^{2} ] + {A}_{{\_ LO}_{1}}^{2} + {A}_{{\_ LO}_{2}}^{2} + 2 {A}_{{\_ RF}_{1}} {A}_{{\_ LO}_{1}} {{G}_{{\_ RF}_{1}} [ {{I}_{1} ( t )}^{2} + {{Q}_{1} ( t )}^{2} ]}^{\hat{} ( 1 / 2 )} cos ( {ω}_{{\_ LO}_{1}} t - {ω}_{{\_ RF}_{1}} t + {Φ}_{{\_ LO}_{1}} - {θ}_{{\_ RF}_{1}} ) + 2 {A}_{{\_ RF}_{2}} {A}_{{\_ LO}_{2}} {{G}_{{\_ RF}_{2}} [ {{I}_{2} ( t )}^{2} + {{Q}_{2} ( t )}^{2} ]}^{\hat{} ( 1 / 2 )} cos ( {ω}_{{\_ LO}_{2}} t - {ω}_{{\_ RF}_{2}} t + {Φ}_{{\_ LO}_{2}} - {θ}_{{\_ RF}_{2}} ) + 2 {A}_{{\_ LO}_{1}} {A}_{{\_ LO}_{2}} cos ( {ω}_{{\_ LO}_{1}} t - {ω}_{{\_ LO}_{2}} t + {Φ}_{{\_ LO}_{1}} - {Φ}_{{\_ LO}_{2}} ) + 2 {A}_{{\_ RF}_{1}} {A}_{{\_ LO}_{2}} {{G}_{{\_ RF}_{1}} [ {{I}_{1} ( t )}^{2} + {{Q}_{1} ( t )}^{2} ]}^{\hat{} ( 1 / 2 )} cos ( {ω}_{{\_ LO}_{2}} t - {ω}_{{\_ RF}_{1}} t + {Φ}_{{\_ LO}_{2}} - {θ}_{{\_ RF}_{1}} ) + 2 {A}_{{\_ RF}_{2}} {A}_{{\_ LO}_{1}} {{G}_{{\_ RF}_{2}} [ {{I}_{1} ( t )}^{2} + {{Q}_{1} ( t )}^{2} ]}^{\hat{} ( 1 / 2 )} cos ( {ω}_{{\_ RF}_{2}} t - {ω}_{{\_ LO}_{1}} t + {θ}_{{\_ RF}_{2}} - {Φ}_{{\_ LO}_{1}} ) + 2 {G}_{{\_ RF}_{1}} {{{G}_{{\_ RF}_{2}} [ {{I}_{1} ( t )}^{2} + {{Q}_{1} ( t )}^{2} ]}^{\hat{} ( 1 / 2 )} [ {{I}_{2} ( t )}^{2} + {{Q}_{2} ( t )}^{2} ]}^{\hat{} ( 1 / 2 )} cos ( {ω}_{{\_ RF}_{2}} t - {ω}_{{\_ RF}_{1}} t + {θ}_{{\_ RF}_{2}} - {θ}_{{\_ RF}_{1}} ) ] \qquad ( 5 )$$

The receiving units 104 and 106 may comprise a first and a second set of low-pass filters (LPFs) 126 and 128, operating amplifiers (OPs) 130 and 132, and analog-to-digital converters (ADCs) 134 and 136. Each set being located after the power detector diodes 122 and 124. Other high-order harmonic components are not considered because they may be removed by the LPFs 126 and 128 to provide low-pass output signals. The desired interferometer signals, i.e., S_{_out1}(t)=2A_{_RF1}A_{_LO1} G_{_RF1}[I₁(t)²+Q₁(t)²]\hat{ }^{(1/2)}cos(W_{_Lo1}t−W_{_RF1}t+Φ_{_LO1}−θ_{_RF1}) and S_{_out2}(t)=2A_{_RF2}A_{_LO2}G_{_RF2}[I₂(t)²+Q₂(t)²]\hat{ }^{(1/2)} cos(W_{_LO2}t−W_{_RF2}t+Φ_{_LO2}−θ_{_RF2}) are then amplified by the OPs 130 and 132 and sent to the ADCs 134 and 136 as amplified output signals. Then subsequent digital signal processing (DSP) 138 retrieves the data stream as digital output signals from the ADCs 134 and 136. In this manner, the receiving units 104 and 106 may demodulate RF signals with half of the number of power detectors, LPs, OPs, and ADCs compared with conventional six-port receivers, reducing the system complexity and energy consumption.

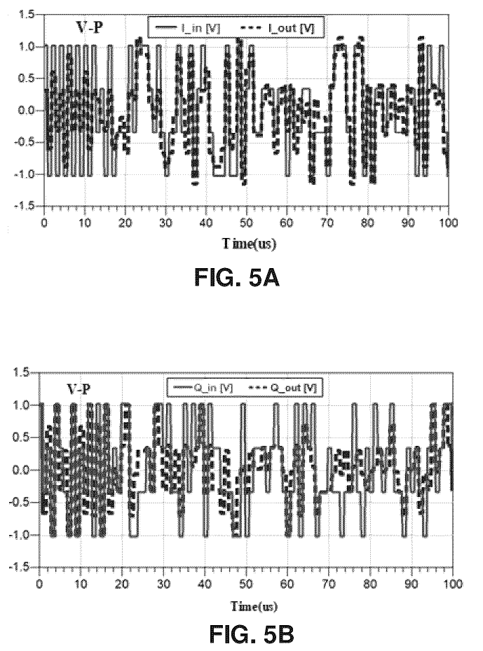

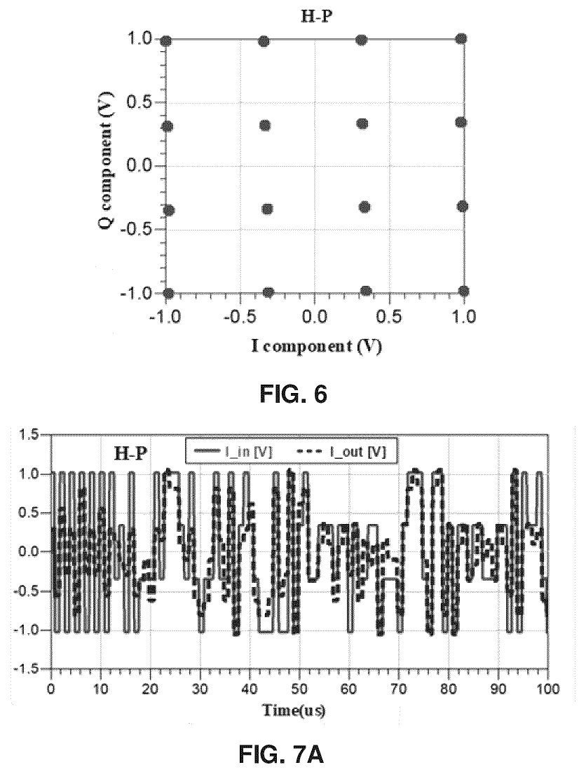

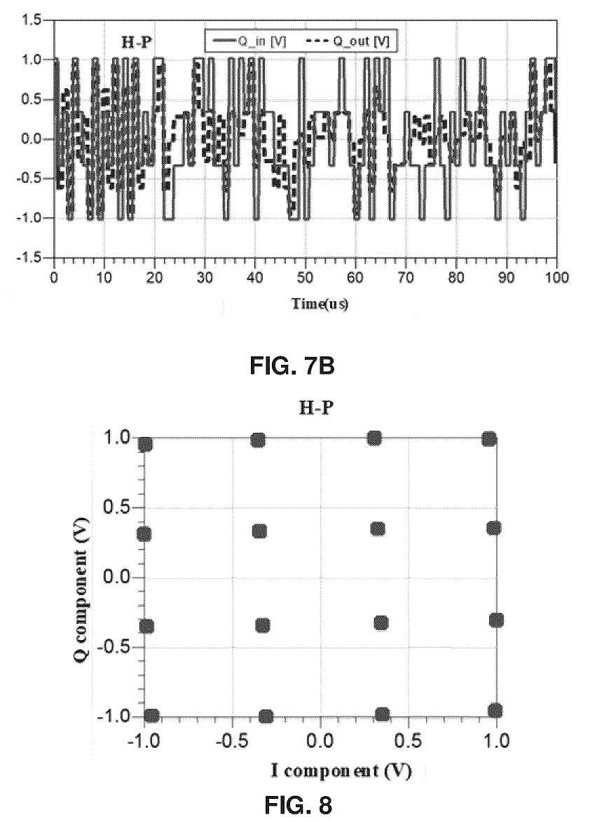

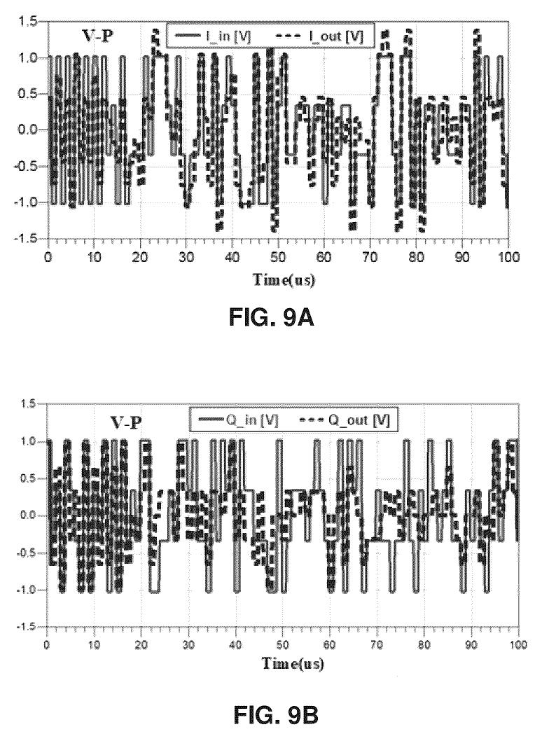

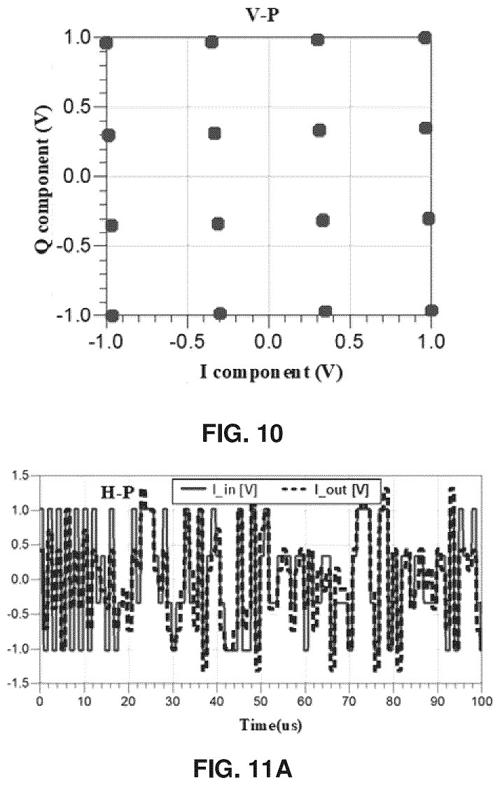

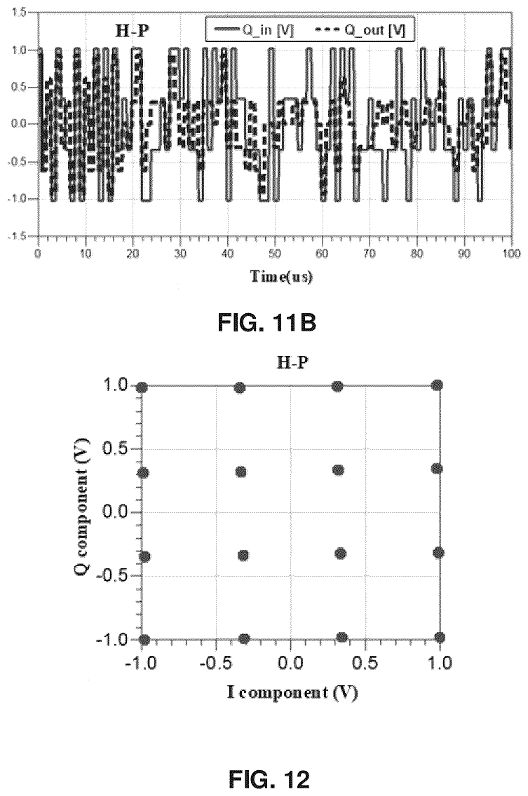

The receiving module 100 described herein may be suitable for multi-channel, multi-function, and multi-standard wireless systems. The receiving module 100 may be implemented with a low-cost substrate-integrated waveguide structure. By way of illustration, FIGS. 5A and 5B illustrate the waveforms of the input and output I and Q signals for vertical polarization, wherein the signals I and Q represent a pseudo-random sequence for modulating a 16 quadrature amplitude modulation (QAM) signal with 50 mega samples per second (MSps) at a 24-GHz carrier frequency. FIGS. 5A and 5B illustrate that the output signals I_out and Q_out are substantially identical to the input signals I_In and Q_In. FIG. 6 shows the demodulated vertical polarization normalized constellation diagram of the signals of FIGS. 5A and 5B. FIGS. 7A and 7B similarly illustrate the waveforms of the input and output I and Q signals for horizontal polarization, wherein the signals I and Q represent a pseudo-random sequence, which modulates the 16 QAM signal with 50-MSps at 24-GHz carrier frequency. FIGS. 7A and 7B illustrate that the output signals I_out and Q_out are substantially identical to the input signals I_In and Q_In. FIG. 8 shows the demodulated horizontal polarization normalized constellation diagram of the signals of FIGS. 7A and 7B. To illustrate the concurrent operating, FIGS. 9A and 9B illustrate the waveforms of the input and output I and Q signals for vertical polarization, which modulates the 16 QAM signal with 50-MSps at a 28-GHz carrier frequency. FIGS. 9A and 9B illustrate that the output signals I_out and Q_out are substantially identical to the input signals I_In and Q_In. FIG. 10 shows the demodulated vertical polarization normalized constellation diagram of the signals of FIGS. 9A and 9B. FIGS. 11A and 11B illustrate the waveforms of the input and output I and Q signals for horizontal polarization, which modulates the 16 QAM signal with 50-MSps at a 28-GHz carrier frequency. FIGS. 11A and 11B illustrate that the output signals I_out and Q_out are substantially identical to the input signals I_In and Q_In. FIG. 12 shows the demodulated horizontal polarization normalized constellation diagram of the signals of FIGS. 11A and 11B.

When the LO signal of the receiver change to four different frequencies, i.e., V_{_LO1}=ƒ₁, V__{LO2}=ƒ₂, H_{_LO1}=ƒ₃, and H_{_LO4}=ƒ₄, the receiver module 100 may also concurrently demodulate independent data streams from four different modulated signals i.e., V_{_RF1}=ƒ₁, V_{_RF}=ƒ₂, H_{_RF1}=ƒ₃, and H_{_RF2}=ƒ₄. Thus, concurrent transmission ability of the receiver module 100 may be four times compared with conventional six-port receivers.

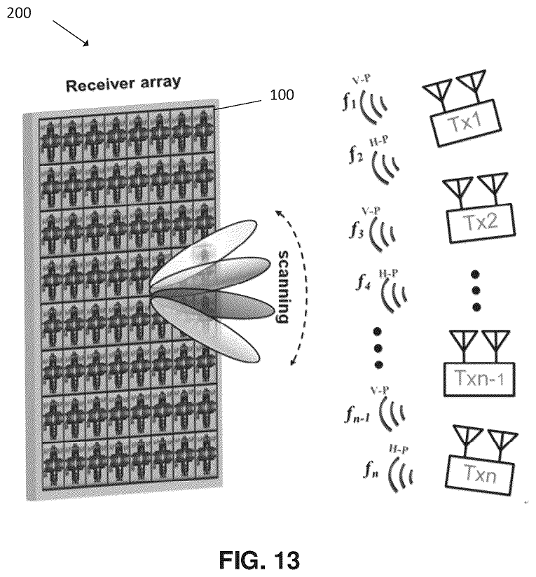

The receiver modules 100 and 160 may be arranged, assembled, constructed, and/or the like in a receiver array 200 as illustrated in FIG. 13. The receiver array 200 may enable multi-beam scanning to receive modulated signals having different frequencies. The receiver array 200 may be used for multi-function applications such as sensing, imaging, angle/polarization detection, and/or the like, and may be implemented with PCB, metallic waveguides, CMOS, silicon micromachining, and/or the like.

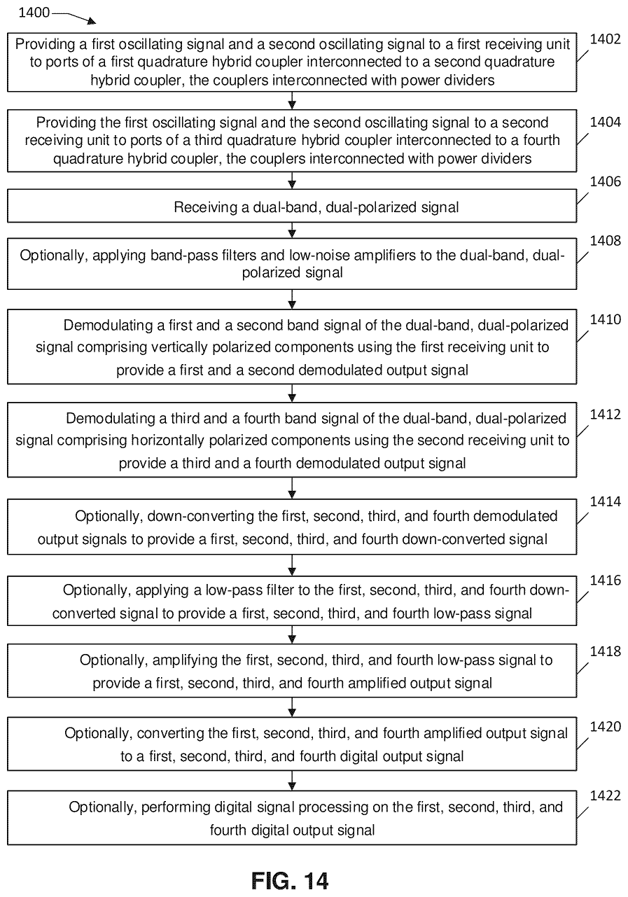

FIG. 14 is a flowchart showing the steps of a method 1400, according to some embodiments of the present disclosure. The method 1400 begins with providing a first oscillating signal and a second oscillating signal to a first receiving unit to ports of a first quadrature hybrid coupler interconnected to a second quadrature hybrid coupler, the couplers interconnected with power dividers (step 1402). At step 1404, the first oscillating signal and the second oscillating signal are provided to a second receiving unit to ports of a third quadrature hybrid coupler interconnected to a fourth quadrature hybrid coupler, the couplers interconnected with power dividers. At step 1406, a dual-band, dual-polarized signal is received. Optionally, at step 1408, band-pass filters and low-noise amplifiers are applied to the dual-band, dual-polarized signal. Optionally, at step 1410, a first and a second band signal of the dual-band, dual-polarized signal are demodulated comprising vertically polarized components using the first receiving unit to provide a first and a second demodulated output signal. Optionally, at step 1412, a third and a fourth band signal of the dual-band, dual-polarized signal are demodulated comprising horizontally polarized components using the second receiving unit to provide a third and a fourth demodulated output signal. Optionally, at step 1414, the first, second, third, and fourth demodulated output signals are down-converted to provide a first, second, third, and fourth down-converted signal. Optionally, at step 1416, a low-pass filter is applied to the first, second, third, and fourth down-converted signal to provide a first, second, third, and fourth low-pass signal. Optionally, at step 1418, the first, second, third, and fourth low-pass signal are amplified to provide a first, second, third, and fourth amplified output signal. Optionally, at step 1420, the first, second, third, and fourth amplified output signal are converted to a first, second, third, and fourth digital output signal. Optionally, at step 1422, digital signal processing is performed on the first, second, third, and fourth digital output signal.

Embodiments have been described above in conjunctions with aspects of the present invention upon which they may be implemented. Those skilled in the art will appreciate that embodiments may be implemented in conjunction with the aspect with which they are described, but may also be implemented with other embodiments of that aspect. When embodiments are mutually exclusive, or are otherwise incompatible with each other, it will be apparent to those skilled in the art. Some embodiments may be described in relation to one aspect, but may also be applicable to other aspects, as will be apparent to those of skill in the art.

Although the present invention has been described with reference to specific features and embodiments thereof, it is evident that various modifications and combinations may be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

1. A circuit comprising:
a first receiving unit and a second receiving unit, each receiving unit of the first receiving unit and the second receiving unit comprising:
a 90-degree phase shifter;
a first power divider and a second power divider, each power divider of the first power divider and the second power divider comprising a first input port, a second input port, and an output port; and
a first quadrature hybrid coupler and a second quadrature hybrid coupler, each quadrature hybrid coupler of the first quadrature hybrid coupler and the second quadrature hybrid coupler comprising a first port, a second port, a third port, and a fourth port,
wherein:
the first port of the first quadrature hybrid coupler is for being energized by a first oscillation signal,
the second port of the first quadrature hybrid coupler is connected to the second input port of the first power divider,
the third port of the first quadrature hybrid coupler is connected to the second input port of the second power divider,
the fourth port of the first quadrature hybrid coupler is for being energized by a second oscillation signal,
the first port of the second quadrature hybrid coupler is for being energized by a first input signal,
the second port of the second quadrature hybrid coupler is connected to the first input port of the first power divider via the 90-degree phase shifter,
the third port of the second quadrature hybrid coupler is connected to the first input port of the second power divider,
the fourth port of the second quadrature hybrid coupler is for being energized by a second input signal,
each output port of each power divider of the first power divider and the second power divider is for being energized by a demodulated output signal.

2. The circuit of claim 1, further comprising:
a dual polarization antenna for receiving dual-band signals comprising vertically polarized components and horizontally polarized components, the dual polarization antenna for providing:
a first band signal comprising first vertically polarized components as the first input signal to the first receiving unit;
a second band signal comprising second vertically polarized components as the second input signal to the first receiving unit;
a third band signal comprising first horizontally polarized components as a third input signal to the second receiving unit; and
a fourth band signal comprising second horizontally polarized components as a fourth input signal to the first receiving unit.

3. The circuit of claim 1, wherein each of the first port and the fourth port of the second quadrature hybrid coupler of the first receiving unit and the second receiving unit comprises:
a band-pass frequency filter for converting:
the first input signal to a first band-pass signal; and
the second input signal to a second band-pass signal.

4. The circuit of claim 3, wherein each of the first port and the fourth port of the second quadrature hybrid coupler comprises a low-noise amplifier for converting:
a first band-pass signal to a first low-noise amplified signal; and
a second band-pass signal to a second low-noise amplified signal.

5. The circuit of claim 1, wherein the output port of each power divider of the first power divider and the second power divider comprises a power detector to convert the demodulated output signal to a down-converted output signal.

6. The circuit of claim 5, wherein the output port of each power divider of the first power divider and the second power divider comprises a low-pass filter to convert the down-converted output signal to a low-pass output signal.

7. The circuit of claim 6, wherein the output port of each power divider of the first power divider and the second power divider comprises an operating amplifier to amplify the low-pass output signal to an amplified output signal.

8. The circuit of claim 7, wherein the output port of each power divider of the first power divider and the second power divider comprises an analog-to-digital converter to convert the amplified output signal to a digital output signal.

9. The circuit of claim 8, further comprising:
a digital signal processor for processing the digital output signal.

10. The circuit of claim 1, further comprising:
a first local oscillator for producing the first oscillation signal; and
a second local oscillator for producing the second oscillation signal.

11. The circuit of claim 10, wherein the first local oscillator and the second local oscillator have substantially the same characteristic impedance.

12. The circuit of claim 1, wherein the circuit further comprises:
complementary metal-oxide-semiconductor (CMOS) components.

13. The circuit of claim 1, wherein the first receiving unit and the second receiving unit are vertically integrated on different CMOS layers.

14. A receiving array comprising a plurality of circuits each comprising:
a first receiving unit and a second receiving unit, each receiving unit of the first receiving unit and the second receiving unit comprising:
a 90-degree phase shifter;
a first power divider and a second power divider, each power divider of the first power divider and the second power divider comprising a first input port, a second input port, and an output port; and
a first quadrature hybrid coupler and a second quadrature hybrid coupler, each quadrature hybrid coupler of the first quadrature hybrid coupler and the second quadrature hybrid coupler comprising a first port, a second port, a third port, and a fourth port,
wherein:
the first port of the first quadrature hybrid coupler is for being energized by a first oscillation signal,
the second port of the first quadrature hybrid coupler is connected to the second input port of the first power divider,
the third port of the first quadrature hybrid coupler is connected to the second input port of the second power divider,
the fourth port of the first quadrature hybrid coupler is for being energized by a second oscillation signal,
the first port of the second quadrature hybrid coupler is for being energized by a first input signal,
the second port of the second quadrature hybrid coupler is connected to the first input port of the first power divider via the 90-degree phase shifter,
the third port of the second quadrature hybrid coupler is connected to the first input port of the second power divider,
the fourth port of the second quadrature hybrid coupler is for being energized by a second input signal,
each output port of each power divider of the first power divider and the second power divider is for being energized by a demodulated output signal.

15. A method comprising:
providing a first oscillating signal and a second oscillating signal to a first receiving unit to ports of a first quadrature hybrid coupler interconnected to a second quadrature hybrid coupler, the first quadrature hybrid coupler and the second quadrature hybrid coupler interconnected with power dividers;
providing the first oscillating signal and the second oscillating signal to a second receiving unit to ports of a third quadrature hybrid coupler interconnected to a fourth quadrature hybrid coupler, the third quadrature hybrid coupler and the fourth quadrature hybrid coupler interconnected with power dividers;
receiving a dual-band dual-polarized signal;
demodulating a first band signal of the dual-band dual-polarized signal comprising first vertically polarized components using the first receiving unit to provide a first demodulated output signal;
demodulating a second band signal of the dual-band dual-polarized signal comprising second vertically polarized components using the first receiving unit to provide a second demodulated output signal;
demodulating a third band signal of the dual-band dual-polarized signal comprising first horizontally polarized components using the second receiving unit to provide a third demodulated output signal; and
demodulating a fourth band signal of the dual-band dual-polarized signal comprising second horizontally polarized components using the second receiving unit to provide a fourth demodulated output signal.

16. The method of claim 15, further comprising:
applying a band-pass filter and a low-noise amplifier to:
a first band intermediate signal the dual-band dual-polarized signal comprising the first vertically polarized components to provide the first band signal;
a second band intermediate signal of the dual-band dual-polarized signal comprising the second vertically polarized components to provide the second band signal;
a third band intermediate signal of the dual-band dual-polarized signal comprising the first horizontally polarized components to provide the third band signal; and
a fourth band intermediate signal of the dual-band dual-polarized signal comprising the second horizontally polarized components to provide the fourth band signal.

17. The method of claim 15, further comprising:
down-converting the first demodulated output signal, the second demodulated output signal, the third demodulated output signal, and the fourth demodulated output signal to a first down-converted output signal, a second down-converted output signal, a third down-converted output signal, and a fourth down-converted output signal, respectively.

18. The method of claim 17, further comprising:
applying a low-pass filter to the first down-converted output signal, the second down-converted output signal, the third down-converted output signal, and the fourth down-converted output signal to produce a first low-pass output signal, a second low-pass output signal, a third low-pass output signal, and a fourth low-pass output signal, respectively.

19. The method of claim 18, further comprising:
amplifying the first low-pass output signal, the second low-pass output signal, the third low-pass output signal, and the fourth low-pass output signal to a first amplified output signal, a second amplified output signal, a third amplified output signal, and a fourth amplified output signal, respectively.

20. The method of claim 19, further comprising:
converting the first amplified output signal, the second amplified output signal, the third amplified output signal, and the fourth amplified output signal to a first digital output signal, a second digital output signal, a third digital output signal, and a fourth digital output signal, respectively.
